(19) United States
(12) Patent Application Publication
(10) Pub. No.: US 2003/0003783 A1
(43) Pub. Date: Jan. 2, 2003

(54) Replaceable module for a notebook computer

(76) Inventors: Sung-Ming Song, Taipei (TW); Kai-Yuan Cheng, Taipei (TW); Feng-Chi Liu, Taipei (TW)

Correspondence Address: BACON & THOMAS, PLLC, 625 SLATERS LANE, FOURTH FLOOR, ALEXANDRIA, VA, 22314

(21) Appl. No.: 09/894,130

(22) Filed: Jun. 29, 2001

(51) Int. Cl. H05K 1/00

(52) U.S. Cl. 439/76.1

(57) ABSTRACT

The present invention relates to a replaceable module for a notebook computer, the said module is disposed on an external housing body of a display apparatus of a notebook computer, a component with at least one function is installed on a circuit board mounted inside the said module, thereby when the said module is connected onto the said external housing body, the said notebook computer can utilize the function possessed by the said module; while the said notebook computer needs to utilize another function, it is only necessary to install the said module mounted with another circuit board of the said another function to the said notebook computer, thereby to facilitate the notebook computer to conduct upgrading and maintenance.

### BACKGROUND OF THE INVENTION

In the recent years, due to the continuous improvement of the electronic technology, the capability of the notebook computer and its peripheral products have been enhanced unceasingly. Various new kinds of peripheral products have substituted the old ones and the prices are even lower than before, that makes the notebook computer and its peripheral products become more available in our daily work, study and life, therefore people's request for the notebook computer grows rapidly. Facing such a wide and rising consuming market, all the major manufactures of notebook computers and its peripheral products are making their full effort to strive. Therefore, in this market full of challenges and competitions, every major manufacturer pre-installs various kinds of chips of peripheral products, wherein the familiar sound card and the modem are the most popular ones, on the mother board in the notebook computer to stimulate the consumers to choose the computer and its peripheral product made by the manufacturer in order to make own products attract a wide range of consumer groups so as to occupy more market niches. Consequently, usually several chips of different functions are already installed on the mother board in a newly purchased notebook computer to satisfy the basic need of the general consumers and to provide the computer manufacturer with an advantageous condition for opening up more business opportunities in the market.

Furthermore, the developmental trend of the notebook computer is to make thin, short and small size for convenient carry. All the major manufacturers continuously research, develop and attempt to reduce the weight and the thickness of the notebook computer. Wherein most of the general methods for reducing the weight of the notebook computer adapt the ways of changing the material of all the components, more especially, the housing body of the notebook computer is made of lighter alloy; the ways of reducing the thickness of the notebook computer art to try the best to integrate various components to be used on the same chip and to install it on the mother board in the notebook computer, thereby to tremendously reduce the thickness of the notebook computer.

However, the new peripheral products of the notebook computer keep coming out and the number of different chips and related components has been increased on the mother board in the notebook computer for satisfying the consumer's needs. That gradually results in insufficiently useable space on the circuit board and incapability of increasing new chips and related components. It is necessary to increase the length and width of the mother board for increasing the space on the mother board for installing the new chips and related components. It is against the original purpose of trending toward the thin, short and small size as well as convenient carry. Furthermore, since there are too many components installed on the mother board, when one of the components breaks down, the inspection and testing fee for the mother board is relative high and when situation like this happens, usually the whole notebook computer unit has to be sent for maintenance and that might cause trouble and a lot of inconvenience in use.

### SUMMARY OF THE INVENTION

In view of the mentioned reasons, in order to improve the insufficient installing space of the conventional notebook computer, the incapability of obtaining convenient upgrade and maintenance, the inventor of the present invention, following long endeavor to research and experiment, finally culminated in the development of the present invention of a replaceable module for a notebook computer, the said module is disposed on an external housing body of a display apparatus of a notebook computer, a component with at least one function is installed on a circuit board mounted inside the said module, thereby when the said module is connected onto the said notebook computer, the said notebook computer can utilize the function possessed by the said module; while the said notebook computer needs to utilize another function, it is only necessary to install the module possessing that function to the said notebook computer, thereby to facilitate the notebook computer to conduct upgrading and maintenance.

### BRIEF DESCRIPTION OF THE DRAWINGS

FIG. 1 is a schematic drawing of the external view of the present invention.

FIG. 2 is a schematic drawing of the module of the present invention.

FIG. 3 is a schematic drawing of the circuit board of the present invention.

FIG. 4 is a schematic drawing of the insert slot of the present invention.

FIG. 5 is a schematic drawing of the external view of another exemplary embodiment of the present invention.

### DETAILED DESCRIPTION OF THE PREFERRED EMBODIMENTS

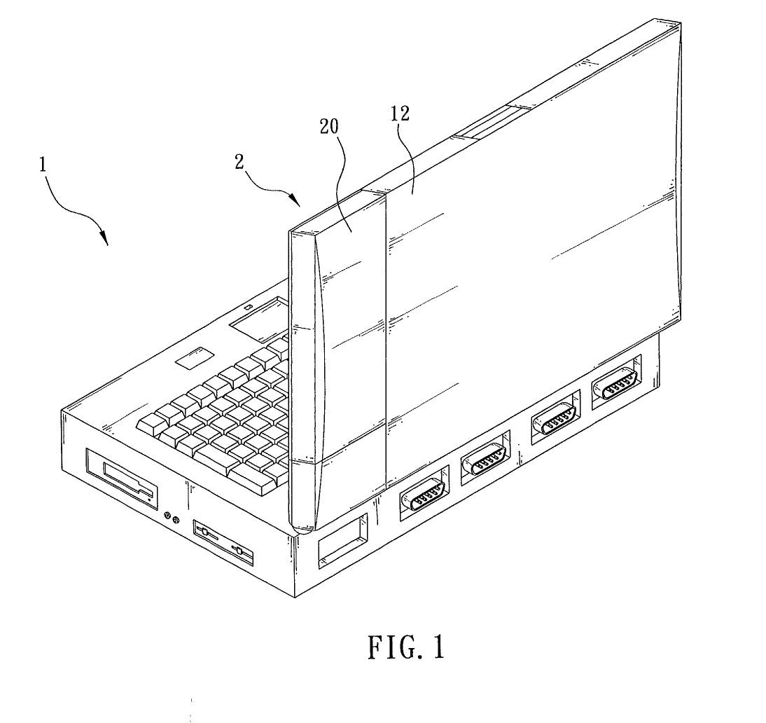

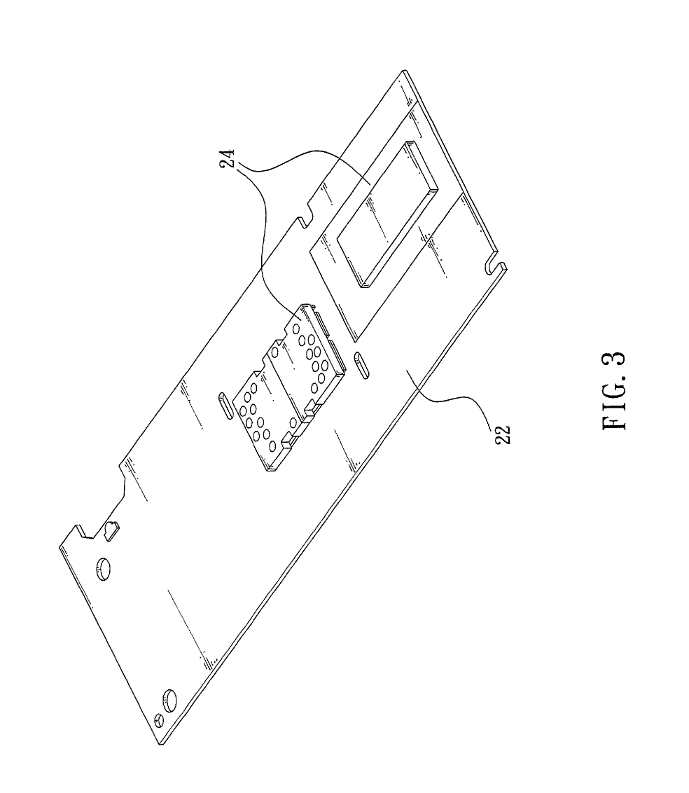

The present invention is a replaceable module for a notebook computer, referring to FIGS. 1 to 5, the said module (2) is disposed on an external housing body (12) of a display apparatus of a notebook computer (1), the said module (2) comprises a machine housing (20) able to fitly connect with the said external housing body (12) to form a unitary shape together, a circuit board (22) disposed in the inner side of the said machine housing (20), a plurality of components (24) mounted on the said circuit board (22) to make the said circuit board (22) at least available for conducting one functional operation (such as the interfaces of image capture, bluetooth communication or area network) for the said notebook computer (1), and a connector (26) disposed at a proper position on one side of the said circuit board (22) opposite to the said machine housing (20). The said connector (26) is used to connect with another connector (122) disposed on the said external housing body (12) while the said machine housing (20) being connected with the said external housing body (12) together, the said another connector (122) also connects with the circuit of the said display apparatus to make the signal generated on the said circuit board (22) transmit to the said mother board via the said circuit for conducting operation, thereby when the said notebook computer needs to utilize another function, it is only necessary to install another module having the same function to the said notebook computer, that means, the said notebook computer is convenient for operations of upgrading and maintenance, etc.

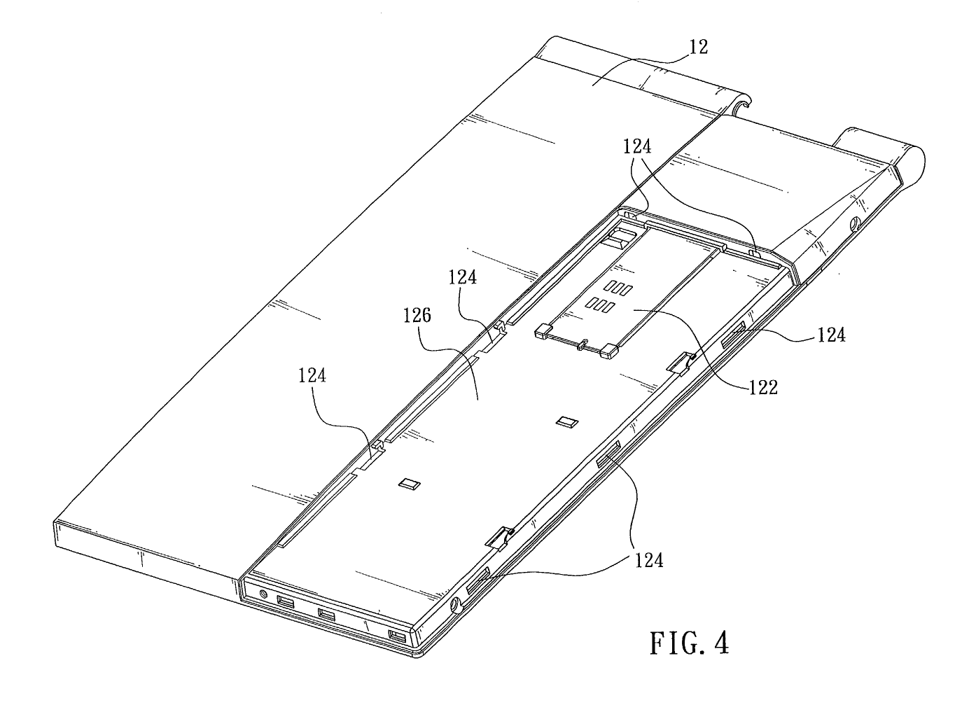

In the present invention, referring to FIG. 4, in order to make the said machine housing (20) do not project out on the surface of the said external housing body (12) to increase the entire thickness of the said notebook computer (1), an insert slot (126) is concavely disposed at a proper position on the surface of the said external housing body (12), the said machine housing (20) can be fitly inserted into the said insert slot (126) to make the external view of the said machine housing (20) and the said external housing body (12) be an unitary shape without increasing the entire thickness of the said notebook computer (1).

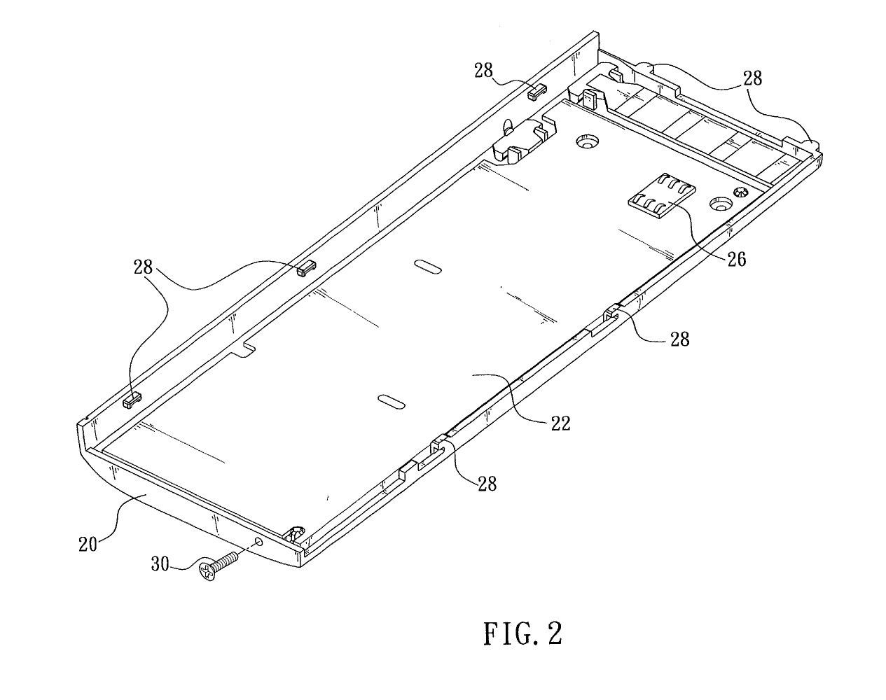

In the present invention, referring to FIGS. 2 and 4, the said connector (26) is disposed with a plurality of resilient electric contact points, the said electric contact points connect with the said circuit board (22), the said circuit board (22) receives or sends out signals through the said electric contact points, thereby, when the ends of the said electric contact points are pushed against by an object, the ends of the said electric contact points is moved inwardly toward the inner side of the said machine housing (20), at the mean time, the resilient forces thereof press these ends against the said object, that means, the said electric contact points can tightly press against any object pushed against thereon; another plane-shaped electric contact point is respectively inserted on the surface, relative to the said electric contact points, of the said another connector (122) on the external housing body (12), the said another electric contact point connects with the circuit of the said display apparatus to make the said another electric contact point capable of receiving signals from the said circuit or sending out signals to the said circuit, thereby when the said machine housing (20) is inserted on the said external housing body (12), the said electric contact points and the said another electric contact point connects with each other to enable the said circuit board (22) and the said mother board to transmit signals mutually.

Since the said electric contact point and another electric contact point are the preferred embodiment of the said connector (26) and another connector (122), in the present invention, the said connector (26) and another connector (122) can be electric connectors of various types and regulations, such as the male and the female coupling contacts of USB connector or the coupling contacts, insert slots or the others of the gold finger.

In the present invention, referring again to FIGS. 2 and 4, a plurality of locking components (28) are disposed at the proper positions on the said machine housing (20), another locking component (124) is respectively mounted at the position of the said external housing body (12) relative to the said locking components (28), thereby when the said machine housing (20) connects with the said external housing body (12), the said locking components (28) match with the said another locking component (124) to prevent the machine housing (20) from falling off from the said external housing body (12); the said circuit board (22) is moveably disposed on the said machine housing (20), thereby when the said circuit board (22) breaks down, the said circuit board (22) can be dismounted alone from the said machine housing (20) for maintenance while the said machine housing (20) still connects onto the said external housing body (12) to make the said notebook computer (1) keep a complete external view.

In the present invention, in order to prevent the said machine housing (20) from falling off from the said external housing body (12) caused by bumping from external force when the said machine housing (20) connects with the external housing body (12), at least one engaging component (30), such as a screw, is disposed at another proper position on the said machine housing (20); another engaging component (32), such as a threaded hole, is disposed on the said external housing body (12) to fit with the said engaging component (30), thereby when the said machine housing (20) and the external housing body (12) matches with each other and the said engaging component (30) engages another engaging component (32), the said machine housing (20) and the said external housing body (12) can be connected more stably and be uneasy to fall off.

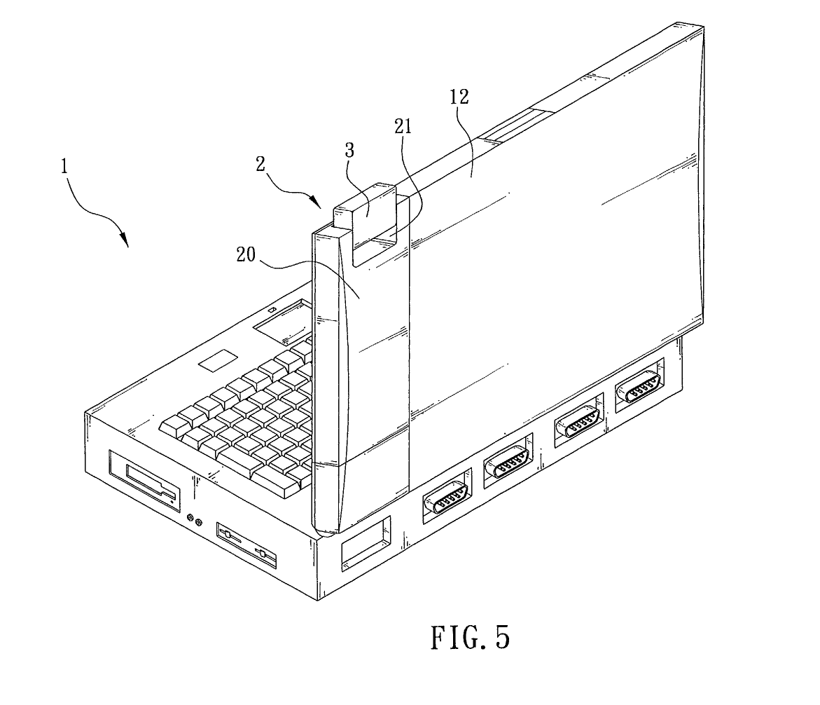

In the present invention, referring to FIG. 5, a concave section (21) is concavely disposed at a proper position on the said machine housing (20), a signal input component (3), such as a lens of an image capturer, is moveably disposed on the said concave section (21) to make the said signal input component (3) capable of moving up-and-down at the position of the said concave section (21), the said signal input component (3) connects with the said circuit board (22) to transmit the signal of the said signal input component (3), after being operated by the said related components (24) installed on the said circuit board (22), to the said mother board via the circuit of the said display apparatus for conducting follow-up operations.

Since the presently available computer operating system is capable of judging by itself to see whether a new peripheral product is added or an originally connected peripheral product is off-line, then conducting proper operation by itself without influencing the basic operation of the computer, therefore, all the components on the said circuit board (22) are of the peripheral components, thereby when the said circuit board (22) is sent for maintenance, the said notebook computer (1) can be used continuously.

1. A replaceable module for a notebook computer with an insert slot concavely disposed on the surface of an external housing body of a display apparatus of the said notebook computer comprises of:
a machine housing, the said machine housing can be fitly inserted into the said insert slot to connect the said machine housing together with the said external housing body;
a circuit board, the said circuit board is disposed on the inner side of the said machine housing at the position relative to the said insert slot;
a connector, the said connector is disposed on one side of the said circuit board opposite to the said machine housing;
an another connector, the said another connector is disposed inside the said insert slot at the position relative to the said connector and is connected with the circuit of the said display apparatus;
wherein the said another connector and said connector contact with each other while the said machine housing being inserted into the said insert slot to connect the said machine housing together with the said external housing body.

2. A replaceable module for a notebook computer according to claim 1, wherein the said connector is disposed with a plurality of resilient electric contact points, the said electric contact points connect with the said circuit board, the said circuit board transmits signals through the said electric contact points, the said another connector is disposed with another electric contact point to contact with the said electric contact points respectively.

3. A replaceable module for a notebook computer according to claim 1, wherein, a plurality of first locking components are disposed at the said machine housing, a plurality of second locking component are respectively disposed at the said external housing body at the position relative to the said first locking component, thereby when the said machine housing connects with the said external housing body, the said first locking components and second locking component match with each other.

4. A replaceable module for a notebook computer according to claim 3, wherein, at least one engaging component is disposed on the said machine housing, another engaging component is disposed on the said external housing body to fit with the said every engaging component.

5. A replaceable module for a notebook computer according to claim 4, wherein, the said engaging component can be a screw, the said another engaging component can be a threaded hole.

6. A replaceable module for a notebook computer according to claim 1, wherein, the said circuit board is moveably disposed on the said machine housing, thereby the said circuit board can be dismounted from the said machine housing.

7. A replaceable module for a notebook computer according to claim 1, wherein, the said connector can be a male contact of an USB connector and the said another connector can be a female contact of an USB connector.

8. A replaceable module for a notebook computer according to claim 1, wherein, the said connector can be a coupling contact of a gold finger and the said another connector can be an insert slot of a gold finger.

9. A replaceable module for a notebook computer according to claim 1, wherein, a concave section is concavely disposed at the said machine housing, the said concave section is moveably disposed with a signal input component connected with the said circuit board.
